(19) United States
(12) Patent Application Publication
(10) Pub. No.: US 2016/0099536 A1
(43) Pub. Date: Apr. 7, 2016

(54) GENERATION OF CONTINUOUS WAVE DUV LASER RADIATION

(71) Applicant: Toptica Photonics AG, Graefelfing (DE)

(72) Inventors: Juergen STUHLER, Grafrath (DE); Matthias SCHOLZ, Muenchen (DE); Thomas Heine, Muenchen (DE)

(73) Assignee: Toptica Photonics AG, Graefelfing (DE)

(21) Appl. No.: 14/504,727

(22) Filed: Oct. 2, 2014

(51) Int. Cl. H01S 3/00; G02F 1/355; G02F 1/35; G02F 1/37; H01S 3/16; H01S 5/14

(52) U.S. Cl. CPC H01S 3/0092; H01S 3/1643; H01S 3/1666; H01S 5/146; G02F 1/3534; G02F 1/37; G02F 1/3532; G02F 1/3551; G02F 2001/354

(57) ABSTRACT

A method for generating continuous wave laser radiation in the deep ultraviolet (DUV) spectral range includes the steps of: generating first laser radiation in the ultraviolet spectral range between 205 nm and 265 nm at a first power level, wherein the generation of the first laser radiation involves not more than two frequency conversion steps; generating second laser radiation in the infrared spectral range at a wavelength of more than 900 nm at a second power level; and sum frequency mixing the first and second laser radiation for generating the laser radiation in the deep ultraviolet spectral range below 205 nm. Moreover, a laser system generates continuous wave laser radiation in the DUV spectral range. According to a preferred embodiment, the DUV laser radiation is tunable in wavelength.

### FIELD OF THE INVENTION

The invention relates to a method for generating continuous wave (cw) laser radiation in the deep ultraviolet spectral range. Further, the invention relates to a laser system for generating cw laser radiation in the deep ultraviolet spectral range.

### BACKGROUND OF THE INVENTION

The need for reliable laser systems in the deep ultraviolet (DUV) wavelength range below 205 nm is continuously growing. Experiments like mercury ion spectroscopy or cooling at 194 nm (W. M. Itano et al. in Laser Manipulation of Atoms and Ions, Proc. Enrico Fermi Summer School, Course CXVIII, Varenna, Italy, July, 1991, edited by E. Arimondo, W. D. Phillips, and F. Strumia, North-Holland, Amsterdam, 1992, pp. 519-537), angle-resolved photo-emission spectroscopy (ARPES) at wavelengths in the range below 205 nm (J. Koralek et al., Phys. Rev. Lett. 96, 017005), DUV Raman spectroscopy (I. Lednev et al., Anal. Bioanal. Chem. 381, pp. 431-437), and industrial testing of semiconductors or optics (T. Tojo et al., Proc. SPIE 5567, 24th Annual BACUS Symposium on Photomask Technology, p. 1011, 2004) would strongly benefit from easy to operate DUV laser sources in the power range of several mW.

However, up to now all existing solutions to generate DUV laser radiation have drawbacks. They either provide pulsed lasers, are based on commercially not available crystals like KBBF/RBBF, provide only low power (<100 μW), or are extremely complex and costly.

For example, J. Sakuma et al. (OPTICS EXPRESS 19, p. 15020, 2011) disclose a frequency-quadrupled YAG laser at 266 nm whose radiation is frequency-mixed with the radiation of a Thulium laser at 1963 nm. The resulting radiation is then frequency-mixed with a resonantly enhanced Ytterbium laser at 1107 nm to obtain 193.4 nm. This known solution hence comprises three lasers and in total four frequency-mixing steps (two second-harmonic stages are included in the 266 nm laser), three of them resonantly enhanced. Therein, the last mixing process to reach 193.4 nm is a resonant one, thus complicating the system and eventually leading to optics degradation.

### SUMMARY OF THE INVENTION

From the foregoing it is readily appreciated that there is a need for an improved method of generating cw radiation in the DUV spectral range. It is an object of the invention to provide a reliable and cost-effective approach of generating cw DUV radiation at a power level of several mW.

In accordance with the invention, a method for generating cw laser radiation in the deep ultraviolet spectral range is disclosed. The method comprises the steps of:
generating first laser radiation in the ultraviolet spectral range between 205 nm and 265 nm at a first power level, wherein the generation of the first laser radiation involves not more than two frequency conversion steps;
generating second laser radiation in the infrared spectral range at a wavelength of more than 900 nm at a second power level; and
sum frequency mixing the first and second laser radiation for generating the laser radiation in the deep ultraviolet spectral range below 205 nm.

The generation of the first laser radiation according to the invention involves not more than two frequency conversion steps. The DUV laser radiation can thus be generated by not more than three frequency conversion steps on the whole, which renders the method of the invention significantly less complicated than all known approaches mentioned herein above.

According to the invention, sum frequency generation (SFG) using a laser apparatus providing radiation in the ultraviolet (UV) spectral range between 205 nm and 265 nm in combination with a high power infrared (IR) laser are employed. High power cw IR lasers (such as, e.g., Raman fiber lasers, Nd:YAG lasers, or other known types of solid state lasers) as well as laser systems delivering cw UV radiation in the respective spectral range are commercially available at comparably low cost.

The low power UV laser radiation (first laser radiation) to be mixed with the IR radiation (second laser radiation) may for example be generated by frequency-doubling or frequency-quadrupling the radiation of a tunable extended cavity diode laser. Appropriate laser sources (e.g. products “TA/FA SHG pro” or “TA/FA FHG pro”) are available from TOPTICA Photonics AG, Grafelfing, Germany. With such a laser source, the generation of the first laser radiation at power levels of 100 mW and more is easily possible, and it can be tuned between 205 nm and 265 nm. Hence, a number of different wavelengths in the DUV range between 180 nm and 205 nm can be made available. In order to achieve tunability of the wavelength of the DUV radiation, the first laser radiation and/or the second laser radiation may tunable in wavelength.

Preferably, the invention uses strongly imbalanced power levels of the first and second laser radiation to achieve a sufficient efficiency in the sum frequency generation step despite using the second laser radiation of relatively low power. High power (several mW) of the generated DUV radiation is obtained according to the invention by sum frequency mixing the high power (1-100 W) IR radiation (second laser radiation) and the low power (several 10 mW up to several 100 mW) UV radiation (first laser radiation). Preferably, the ratio of the second power level to the first power level is between 10 and 2000, more preferred between 100 and 1000.

A further advantage of the method of the invention is that, with the high power of the second laser radiation in the IR spectral range, the sum frequency mixing step of the first and second laser radiation can be performed in a non-resonant fashion (i.e. without resonantly enhancing the amplitude of the laser radiation in the sum frequency mixing step) such that an optical resonator can be dispensed with. This dramatically reduces the complexity of the used system.

Yet another advantage of the method of the invention is that Cesium Lithium Borate (CLBO) may be used in the sum frequency mixing step as a nonlinear optical medium. CLBO is commercially available without limitation, in contrast to “exotic” materials, like KBBF/RBBF, that have to be conventionally employed. CLBO has a high non-linearity, a low absorption in the UV spectral range, and exhibits a moderate “walk off” (the “walk off” describes the mismatch in the propagation direction between the fundamental and the frequency converted radiation within the crystal). The strong light absorption in CLBO below 180 nm imposes a lower wavelength limit for generating DUV radiation according to the invention using this material.

The invention not only relates to a method but also to a laser system for generating laser radiation in the deep ultraviolet spectral range. According to the invention, the system comprises:
a first laser apparatus generating first laser radiation in the ultraviolet spectral range between 205 nm and 265 nm at a first power level, wherein the generation of the first laser radiation involves not more than two frequency conversion steps;
a second laser apparatus generating second laser radiation in the infrared spectral range at a wavelength of more than 900 nm at a second power level; and
a sum frequency generation stage receiving the first and second laser radiation and generating the laser radiation in the deep ultraviolet spectral range below 205 nm.

Preferably, the first laser apparatus comprises a laser source generating laser radiation and one or two cascaded sum frequency generation stages converting the wavelength of the laser radiation of the laser source, wherein the laser source is a tunable extended cavity diode laser—preferably comprising an amplifier stage—and wherein the first laser apparatus further comprises one or two cascaded second harmonic generation stages.

It can be summarized that the invention proposes to use a frequency doubled (or quadrupled) diode laser in a wavelength range between 205 nm and 265 nm and to mix it with a high power IR laser in a single pass setup. The wavelengths of both the UV and the IR radiation are chosen such that (nearly) non-critical phase matching of the sum frequency generation process is possible with CLBO as a nonlinear crystal. Using the available power levels of the individual lasers (several 10 mW up to several 100 mW from the first laser apparatus and up to 100 W from the second laser apparatus) an output power on the order of several mW of the DUV radiation can be obtained.

The advantages of the approach of the invention can be summarized as follows:
Significantly reduced complexity as compared to prior art systems;
Use of commercially available crystals and lasers;
Continuous wave (cw) single frequency operation;
Possibility to generate many different DUV wavelengths below 205 nm;
Tunability of the DUV laser system if a tunable fundamental laser is used in the first laser apparatus.

### BRIEF DESCRIPTION OF THE DRAWINGS

The enclosed drawings disclose preferred embodiments of the present invention. It should be understood, however, that the drawings are designed for the purpose of illustration only and not as a definition of the limits of the invention. In the drawings:

FIG. 1 schematically shows a laser system for carrying out the method of the invention;

FIG. 2 shows the first laser apparatus depicted in FIG. 1 in more detail.

### DETAILED DESCRIPTION OF THE EMBODIMENTS

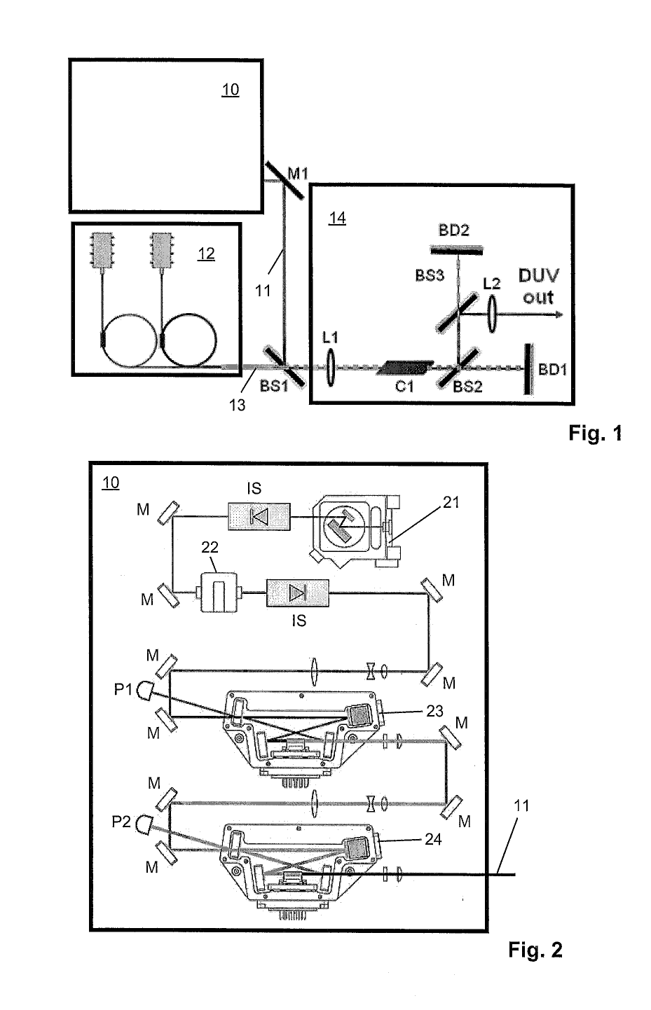

FIG. 1 schematically shows a laser system for generating cw laser radiation in the DUV spectral range. It comprises a first laser apparatus 10 generating first (cw) laser radiation 11 in the UV spectral range between 205 nm and 265 nm at a power level of several 10 mW and up to several 100 mW. The radiation 11 is deflected by a mirror Ml. The system further comprises a second laser apparatus generating second (cw) laser radiation 13 in the IR spectral range at a wavelength of more than 900 nm at a power level of at least 1 W. In the depicted embodiment, the second laser apparatus 12 comprises an IR fiber laser and a fiber amplifier arranged in series. The first and second laser radiation 11, 13 is superposed by a beam splitter BS1 which is highly reflective in the UV and highly transmissive in the IR spectral range. The combined radiation is passed through a non-resonant sum frequency generation stage 14 receiving the first and second laser radiation 11, 13. No provision is made for an optical resonator for enhancing the amplitude of the laser radiation in the sum frequency generation stage 14. The superposed radiation is focused by a lens L1 into a CLBO crystal C1 (operated at 70° C. with a waist of both beams 11, 13 inside the crystal C1) which converts the radiation into laser radiation in the DUV spectral range between 180 nm and 205 nm. Two beam splitters BS2 and BS3 with appropriate reflectivity and transmittance are used to separate the generated DUV radiation from the first and second laser radiation 11, 13 which is then directed onto beam dumps BD1 and BD2 respectively. The DUV radiation passes a collimation lens L2 and exits the system at “DUV out”.

FIG. 2 shows the first laser apparatus 10 of Figure in more detail. The laser apparatus 10 comprises a tunable extended cavity diode laser 21 as a laser source emitting in the IR spectral range between 820 nm and 1060 nm. The radiation passes an optical isolator IS, is amplified by an optical amplifier 22, and passes a further optical isolator IS. The amplified radiation is frequency converted by two cascaded resonant sum-frequency generation stages 23, 24 such that the first laser radiation 11 at the output of the first laser apparatus 10 has a wavelength which is tunable by several nm, in the depicted embodiment, within the wavelength range between 205 nm and 265 nm. Within the first laser apparatus 10 the laser beam is folded several times by mirrors M. Photo diodes P1, P2 are provided for control purposes.

In the following, several examples of DUV generation using the laser system depicted in FIGS. 1 and 2 are listed:
1. DUV radiation at 196 nm is generated with a power level on the order of 5 mW by sum frequency mixing the laser radiation 13 of a 50 W IR laser at 1064 nm (e.g. fiber laser or Nd:YAG laser) and the UV laser radiation 11 at 240 nm and 60 mW (for example generated by the TOPTICA “TA-FHG pro” laser apparatus).
2. DUV radiation at 193.4 nm of about 0.4 mW is generated by sum frequency mixing the laser radiation 13 of a 50 W IR laser at 1530 nm (fiber laser) and the UV laser radiation 11 at 221.4 nm and 30 mW.
3. DUV radiation at 193.4 nm of about 0.8 mW is generated by sum frequency mixing the laser radiation 13 of a 40 W IR laser at 1180 nm (Raman fiber laser) and the UV laser radiation 11 at 231.3 nm and 40 mW.
4. DUV radiation at 193.4 nm of about 1.5 mW is generated by sum frequency mixing the laser radiation 13 of a 40 W IR laser at 1130 nm (Raman fiber laser) and the UV laser radiation 11 at 233.3 nm and 40 mW.
5. DUV radiation at 191.1 nm of about 5 mW is generated by sum frequency mixing the laser radiation 13 of a 40 W IR laser at 1130 nm (Raman fiber laser) and the UV laser radiation 11 at 230 nm and 40 mW.
6. DUV radiation at 187.9 nm of about 3.5 mW is generated by sum frequency mixing the laser radiation 13 of a 40 W IR laser at 1180 nm (Raman fiber laser) and the UV laser radiation 11 at 223.5 nm and 30 mW.
7. DUV radiation at 185 nm or less of about 0.5 mW is generated by sum frequency mixing the laser radiation 13 of a 10 W IR laser at 1260 nm (Raman fiber laser) and the UV laser radiation 11 at 214.5 nm and 30 mW.

Many other wavelengths may be obtained by the depicted system. The system enables the generation of single-frequency DUV laser radiation at wavelengths below 205 nm. The system is fully based on commercially available laser sources and crystals. It is significantly less complex than prior art systems and provides a longer lifetime due to the absence of a resonant enhancement in the last sum frequency mixing step.

1. A method for generating continuous wave laser radiation in the deep ultraviolet spectral range, comprising the steps of:
generating first laser radiation (11) in the ultraviolet spectral range between 205 nm and 265 nm at a first power level, wherein the generation of the first laser radiation (11) involves not more than two frequency conversion steps;
generating second laser radiation (13) in the infrared spectral range at a wavelength of more than 900 nm at a second power level; and
sum frequency mixing the first and second laser radiation (11, 13) for generating the laser radiation in the deep ultraviolet spectral range below 205 nm;
wherein the ratio of the second power level to the first power level is between 10 and 2000; and
wherein the sum frequency mixing step of the first and second laser radiation (11, 13) is non-resonant.

2. The method of claim 1, wherein the ratio of the second power level to the first power level is between 100 and 1000.

3. The method of claim 1, wherein the first power level is in the range between 10 mW and 1000 mW.

4. The method of claim 1, wherein the second power level is in the range between 10 W and 200 W.

5. The method of claim 1, wherein the first laser radiation (11) is generated by frequency-doubling or frequency-quadrupling the radiation of a laser source (21).

6. The method of claim 1, wherein the first laser radiation (11) and/or the second laser radiation (13) are tunable such that the laser radiation in the deep ultraviolet spectral range is tunable.

7. The method of claim 5, wherein the laser source (21) is an extended cavity diode laser.

8. (canceled)

9. A laser system for generating continuous wave laser radiation in the deep ultraviolet spectral range, comprising:
a first laser apparatus (10) generating first laser radiation (11) in the ultraviolet spectral range between 205 nm and 265 nm at a first power level, wherein the generation of the first laser radiation (11) involves not more than two frequency conversion steps;
a second laser apparatus (12) generating second laser radiation (13) in the infrared spectral range at a wavelength of more than 900 nm at a second power level; and
a sum frequency generation stage (14) receiving the first and second laser radiation (11, 13) and generating the laser radiation in the deep ultraviolet spectral range below 205 nm;
wherein the ratio of the second power level (13) to the first power level (11) is between 10 and 2000; and
wherein the sum frequency generation stage (14) is non-resonant.

10. The laser system of claim 9, wherein the ratio of the second power level (13) to the first power level (11) is between 100 and 1000.

11. The laser system of claim 9, wherein the first laser apparatus (10) and/or the second laser apparatus (12) are tunable in wavelength such that the laser radiation in the deep ultraviolet, spectral range is tunable in wavelength.

12. The laser system of claim 9, wherein the first laser apparatus (10) comprises:
a laser source (21) generating laser radiation, and
one or two second harmonic generation stages (23) converting the wavelength of the laser radiation of the laser source (21).

13. The laser system of claim 12, wherein the laser source (21) is a tunable extended cavity diode laser.

14. The laser system of claim 9, wherein the first laser apparatus (10) comprises two cascaded second harmonic generation stages (23, 24).

15. (canceled)

16. The laser system of claim 9, wherein the sum frequency generation stage (14) comprises a Cesium Lithium Borate crystal as a nonlinear optical medium.

17. The laser system of claim 9, wherein the second laser apparatus (12) comprises an infrared fiber laser or a Nd:YAG-Laser.
